(19) United States
(12) Patent Application Publication
(10) Pub. No.: US 2026/0116216 A1
(43) Pub. Date: Apr. 30, 2026

(54) VEHICLE BATTERY MANAGEMENT

(71) Applicant: Rivian IP Holdings, LLC, Irvine, CA (US)

(72) Inventors: Tejas Chafekar, Edwards, IL (US); Yucheng Lin, Burnaby (CA)

(21) Appl. No.: 19/374,400

(22) Filed: Oct. 30, 2025

Related U.S. Application Data
(60) Provisional application No. 63/713,844, filed on Oct. 30, 2024.

(51) Int. Cl. B60L 50/60; G01R 31/36; G01R 31/371; G01R 31/382; G01R 31/54; H01M 10/48

(52) U.S. Cl. CPC B60L 50/60; G01R 31/3646; G01R 31/371; G01R 31/382; G01R 31/54; H01M 10/486

(57) ABSTRACT

Systems, methods, and vehicles are disclosed herein. For example, this disclosure provides for continuous and reliable communication between a battery management system (BMS) and battery sensors and battery power and isolation (BPI) in the event of a breakage. As another example, this disclosure provides for an efficient hardware-based detection method for pressure buildup and thermal events allowing, for example, the BMS to remain asleep, thereby conserving battery power and enabling quicker response times. As another example, this disclosure provides for duty cycling cores while the vehicle is sleeping to provide the BMS an opportunity to measure the actual power draw from a high-voltage (HV) battery pack.

### CROSS-REFERENCE TO RELATED APPLICATIONS

This application claims the benefit of U.S. Provisional Application No. 63/713,844, filed Oct. 30, 2024, the disclosure of which is hereby incorporated by reference herein in its entirety.

### INTRODUCTION

Continuous and reliable communication between sensors in a vehicle and battery management systems of the vehicle is desirable, even in the event of breakages of, e.g., printed circuit board (PCB) traces. Moreover, it is desirable to efficiently and accurately measure pressure buildup in battery packs, and a state-of-charge (SOC) of battery packs in a vehicle, while a battery management system (BMS) is in a sleep mode.

### SUMMARY

As disclosed herein, the present disclosure provides for vehicles, systems, methods, non-transitory computer readable mediums, and apparatuses in which continuous and reliable communication between the BMS and battery sensors and battery power and isolation (BPI) is ensured in the event of a breakage. In some embodiments, the breakage is detected using, e.g., packet error code (PEC), while maintaining vehicle functionality, and notifying the driver.

The disclosed vehicle may comprise a BMS for managing a battery of the vehicle, a first sensor for measuring current of the battery, and a plurality of sensors for measuring voltage and temperature of the battery, wherein each of the plurality of sensors is coupled to at least one other sensor of the plurality of sensors. A first connection from the BMS is split into a first sub-connection coupled to the plurality of sensors and a second sub-connection coupled to the first sensor, and a second connection from the BMS is split into a third sub-connection coupled to the first sensor and a fourth sub-connection coupled to the plurality of sensors. A controller may be configured to cause the BMS to read the voltage and temperature of the battery measured by the plurality of sensors via the first sub-connection of the first connection, and cause the BMS to read the current of the battery measured by the first sensor via the third sub-connection of the second connection. The controller may detect a breakage of the third sub-connection of the second connection, and, based on the detecting, cause the BMS to read the voltage and temperature of the battery measured by the plurality of sensors via the fourth sub-connection of the second connection instead of via the first sub-connection of the first connection, and cause the BMS to read the current of the battery measured by the first sensor via the second sub-connection of the first connection instead of via the third sub-connection of the second connection.

In some embodiments, each of the second sub-connection coupled to the first sensor and the third sub-connection coupled to the first sensor is a trace on a PCB, and each of the first sub-connection coupled to the plurality of sensors and the fourth sub-connection coupled to the plurality of sensors comprise one or more wires that are not traces on a PCB.

In some embodiments, the controller is further configured to, prior to the detecting, alternate between a first configuration and a second configuration, wherein the first configuration comprises the BMS reading the current of the battery measured by the first sensor via the third sub-connection of the second connection and the BMS reading the voltage and temperature measured by the plurality of sensors via the first sub-connection of the first connection. In some embodiments, the second configuration comprises the BMS reading the current of the battery measured by the first sensor via the second sub-connection of the first connection and the BMS reading the voltage and temperature measured by the plurality of sensors via the fourth sub-connection of the second connection.

In some embodiments, the vehicle comprises a first isolation transformer coupled within the first connection and configured to split the first connection into the first sub-connection and the second sub-connection, and a second isolation transformer coupled within the second connection and configured to split the second connection into the third sub-connection and the fourth sub-connection.

In some embodiments, in the vehicle, the first and second connectors employ the serial peripheral interface (SPI) protocol.

In some embodiments, in the vehicle, the controller is configured to detect the breakage based on detecting a threshold number of consecutive PECs.

In some embodiments, in the vehicle, the controller is configured to detect the breakage based on detecting PECs for at least a threshold period of time.

As disclosed herein, the present disclosure provides for vehicles, systems, methods, non-transitory computer readable mediums, and apparatuses in which an efficient hardware-based detection method for pressure buildup and thermal events is utilized, allowing, for example, the BMS to remain asleep, thereby conserving battery power and enabling quicker response times compared to software-based detection methods. Such hardware detection (in which software boot up time does not play a role) of the thermal event based on pressure may be desirable, as purely software may be slow to detect a short-lived spike and react in time. The BMS otherwise may have to always be awake (thus consuming extra power from the high voltage (HV) or 12V battery), or the BMS otherwise has to wake up and complete detection within ˜2 secs (typical signature of the pressure spike), which may not always be feasible.

As disclosed herein, the present disclosure provides for vehicles, systems, methods, non-transitory computer readable mediums, and apparatuses comprising a battery pack and a pressure sensor to monitor a pressure level in the battery pack while a battery management system (BMS) is in a sleep mode, wherein the BMS is configured to monitor the pressure level at a first sampling rate. A battery monitoring circuitry may be configured to generate a signal based on sensor data received from the pressure sensor indicating that the pressure level exceeds a threshold pressure value, and, based on receiving the signal, cause the BMS to wake up from the sleep mode. The BMS may be configured to, after waking up from the sleep mode, perform monitoring of the pressure level at a second sampling rate that is higher than the first sampling rate, and, based on the monitoring of the pressure level by the BMS at the higher rate, determine whether a thermal event is occurring in relation to the battery pack. In some embodiments, the battery monitoring circuitry comprises hardware only, e.g., does not implement executable software instructions.

In the vehicle, the battery monitoring circuitry may be configured to cause the BMS to wake up from the sleep mode using an interrupt signal.

In the vehicle, the signal is a first signal, and the battery monitoring circuitry is further configured to, based on receiving data indicating a rate of change of the pressure level exceeds a threshold value, generate a second signal and transmit the second signal, and cause the BMS to wake up from the sleep mode further based on the second signal.

In the vehicle, the battery monitoring circuitry may be configured to monitor the rate of change of the pressure level, and cause the data indicating the rate of change of the pressure level exceeds the threshold value to be latched, wherein the battery monitoring circuitry receives the latched data.

In the vehicle, the second sampling rate corresponds to real-time monitoring of the pressure level.

In the vehicle, the BMS may be further configured to, based on determining that the thermal event is occurring in relation to the battery pack, initiate an ameliorative action.

In the vehicle, the ameliorative action comprises waking up each of a plurality of other components of the vehicle, deploying one or more pyrotechnic fuses, transmitting a notification to a driver of the vehicle, and/or transmitting a notification to an emergency service.

While the BMS is in a sleep mode, the actual measurement of power being extracted (e.g., additional loads, such as, for example, a security monitoring camera) from the high-voltage (HV) battery cannot be performed by the BMS, and a SOC error may accumulate, causing under-estimation or over-estimation of the SOC. This could lead to higher charging currents that the battery can accept, leading to current limit violations and eventually lithium plating, and/or depletion of the battery.

To help address these issues, the present disclosure provides for vehicles, systems, methods, non-transitory computer readable mediums, and apparatuses for duty cycling cores while the vehicle is sleeping to provide the BMS an opportunity to measure the actual power draw from the HV pack.

A vehicle may be provided comprising a battery, and circuitry configured to, while a battery management system (BMS) is in a sleep mode, cycle on the BMS according to a duty cycle. The BMS may be configured to, after being cycled on, determine a state-of-charge (SOC) of the battery (e.g., based on a measured current draw on the battery when the BMS awakes from the sleep mode).

The vehicle may further comprise memory, wherein the BMS causes the measured current draw to replace a value for the current draw stored in the memory. For example, the battery load is tracked and then updated each cycle. In some embodiments, the value for the current draw may be based on tracking a load of the battery while the BMS is asleep, and the SOC may not be determined until the vehicle (e.g., including the BMS) is to be turned on.

The BMS may cause the measured current draw to replace a value for the current draw stored in the memory based on determining that the value for the current draw stored in the memory deviates from the measured current draw (and/or determined SOC) of the battery by a threshold amount.

The circuitry may be further configured to, while the BMS is in the sleep mode, estimate the SOC of the battery, wherein the value for the SOC stored in the memory corresponds to the estimate.

The circuitry may be further configured to, while the BMS is in the sleep mode, estimate the SOC of the battery, and the BMS may be further configured to, based on determining that the estimate is within a threshold value of the SOC of the battery measured by the BMS, decrease a frequency that the BMS is cycled on by updating the duty cycle. The BMS may be further configured to decrease the frequency that the BMS is cycled on by updating the duty cycle based on determining that each of a plurality of estimated SOCs of the battery calculated while the BMS is in the sleep mode is within the threshold value.

The circuitry may be further configured to, while the BMS is in the sleep mode, estimate the SOC of the battery. The BMS may be further configured to, based on determining that the estimate is not within a threshold value of the SOC of the battery measured by the BMS, increase a frequency that the BMS is cycled on by updating the duty cycle. The BMS may be further configured to increase the frequency that the BMS is cycled on by updating the duty cycle based on determining that each of a plurality of estimated SOCs of the battery calculated while the BMS is in the sleep mode is not within the threshold value.

### BRIEF DESCRIPTION OF THE DRAWINGS

The present disclosure, in accordance with one or more various embodiments, is described in detail with reference to the following figures. The drawings are provided for purposes of illustration only and merely depict typical or example embodiments. These drawings are provided to facilitate an understanding of the concepts disclosed herein and should not be considered limiting of the breadth, scope, or applicability of these concepts. It should be noted that for clarity and ease of illustration, these drawings are not necessarily made to scale.

FIG. 1 shows an illustrative system, in accordance with some embodiments of this disclosure.

FIG. 2 shows a block diagram of a system for managing the provision of sensor data to a battery management system (BMS), in accordance with some embodiments of this disclosure.

FIG. 3 shows an illustrative flowchart for managing the provision of sensor data to a BMS, in accordance with some embodiments of this disclosure.

FIG. 4 shows an illustrative diagram for managing the provision of sensor data to a BMS, in accordance with some embodiments of this disclosure.

FIG. 5 shows an illustrative diagram for managing the provision of sensor data to a BMS, in accordance with some embodiments of this disclosure.

FIG. 6 shows an illustrative diagram for managing the provision of sensor data to a BMS, in accordance with some embodiments of this disclosure.

FIG. 7 shows an illustrative diagram for managing the provision of sensor data to a BMS, in accordance with some embodiments of this disclosure.

FIG. 8 shows an illustrative diagram for managing the provision of sensor data to a BMS, in accordance with some embodiments of this disclosure.

FIG. 9 shows an illustrative system for implementing a bi-directional mode for current and voltage sensing and hardware circuit to detect pressure spikes when a battery pack of a vehicle is undergoing a thermal event, and waking up a BMS via an interrupt, in accordance with some embodiments of this disclosure.

FIG. 10 shows a detailed view of the DV/DT detection circuitry and peak detector circuitry, in accordance with some embodiments of this disclosure.

FIG. 11 shows a detailed view of the DV/DT detection circuitry, in accordance with some embodiments of this disclosure.

FIG. 12 shows a detailed view of the peak detector circuitry, in accordance with some embodiments of this disclosure.

FIG. 13 shows an illustrative flowchart for determining whether a thermal event is occurring in relation to a battery pack based on a monitored pressure level, in accordance with some embodiments of this disclosure.

FIG. 14 shows an illustrative flowchart for cycling on a BMS and measuring a current draw on a battery, in accordance with some embodiments of this disclosure.

### DETAILED DESCRIPTION

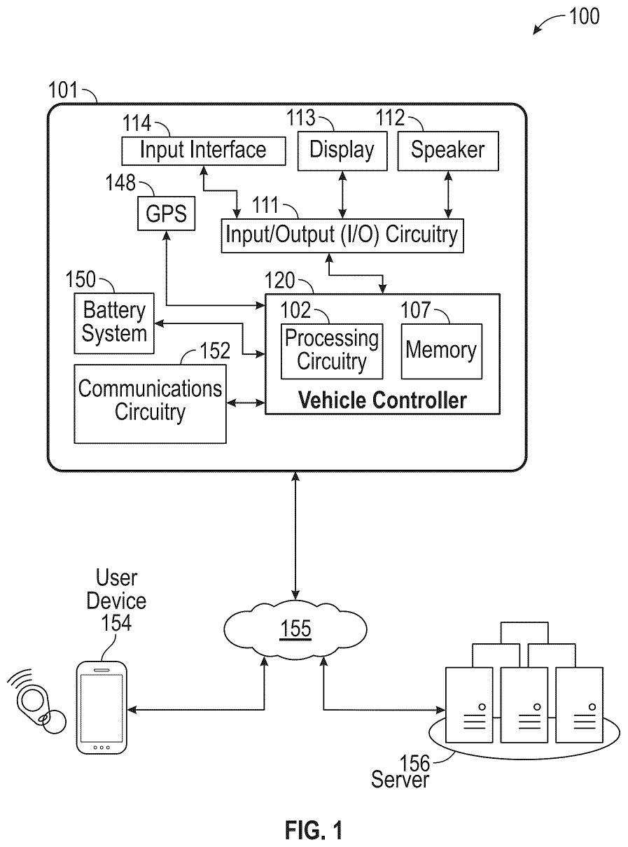

FIG. 1 shows a system 100 comprising electric vehicle 101, in accordance with some embodiments of this disclosure. Vehicle 101 may be a car (e.g., a coupe, a sedan, a truck, an SUV, a bus), a motorcycle, an aircraft (e.g., a drone), a watercraft (e.g., a boat), or any other type of vehicle, or any combination thereof.

Vehicle controller 120 may comprise processing circuitry 102 and memory 107. Processing circuitry 102 of vehicle controller 120 may comprise a hardware processor, a software processor (e.g., a processor emulated using a virtual machine), or any combination thereof. In some embodiments, processing circuitry 102 and memory 107 in combination may be referred to as vehicle controller 120 of vehicle 101. In some embodiments, processing circuitry 102 alone may be referred to as controller vehicle of vehicle 101. Memory 107 may comprise hardware elements for non-transitory storage of commands or instructions, that, when executed by processing circuitry 102, cause processing circuitry 102 to operate vehicle 101 in accordance with embodiments described above and below. Vehicle controller 120 may be communicatively connected to components of vehicle 101 and system 100 via one or more wires, or via wireless connection. In some embodiments, memory 107 may be configured to store electronic data, computer software, or firmware, and may include random-access memory, read-only memory, hard drives, optical drives, solid state devices, or any other suitable fixed or removable storage devices, and/or any combination of the same. Nonvolatile memory may also be used (e.g., to launch a boot-up routine and other instructions). In some embodiments, vehicle controller 120 may include or be in communication with other processing circuitry in vehicle 101 (e.g., an electronic control unit (ECU) of vehicle 101, which may be configured to communicate with other portions of vehicle 101 and perform various tasks.

Vehicle controller 120 may be communicatively connected to electric battery system 150, which may be configured to provide power to one or more of the components of vehicle 101 during operation. In some embodiments, vehicle 101 may be an electric vehicle or a hybrid electric vehicle. Electric battery system 150 may include one or more battery modules, e.g., a 180 kWh battery pack or a 135 kWh battery pack. Vehicle controller 120 may manage the flow of electricity to electric battery system 150 (e.g., to perform AC-DC conversion when the battery of vehicle 101 is charged with an AC charger), and any other suitable components. Vehicle controller 120 may include or monitor, for example, electrical components (e.g., switches, bus bars, resistors, capacitors), control circuitry (e.g., for controlling suitable electrical components), and measurement equipment (e.g., to measure voltage, current, impedance, frequency, temperature, or another parameter) of electric battery system 150.

Battery system 150 and/or vehicle controller 120 may include, for example, signal conditioning circuitry (e.g., filters, amplifiers, voltage dividers), an analog to digital converter, any other suitable circuitry, or any combination thereof. Battery system 150 and/or vehicle controller 120 may, in some embodiments, include a processor, a power supply, power management components (e.g., relays, filters, voltage regulators, differential amplifiers), input/output IO (e.g., general-purpose input/output (GPIO), analog, digital), memory, communications equipment (e.g., CANbus hardware, Modbus hardware, or a WiFi module), any other suitable components, or any combination thereof. In some embodiments, processing circuitry 102 may include one or more microprocessors, microcontrollers, digital signal processors, programmable logic devices, field programmable gate arrays (FPGAs), application-specific integrated circuits (ASICs), etc., and may include a multi-core processor. In some embodiments, battery system 150 and/or vehicle controller 120 may be distributed across multiple separate processors or processing units, for example, multiple of the same type of processing units or multiple different processors.

Battery system 150 and/or vehicle controller 120 may be configured to manage charging of the battery, which may include measuring one or more characteristics of the battery, identifying if a fault has occurred (e.g., in the battery or battery pack), providing power to components of vehicle 101, communicating with a battery charger, any other suitable actions, or any combination thereof. Processing circuitry 102 may include or monitor, for example, electrical components (e.g., switches, bus bars, resistors, capacitors), control circuitry (e.g., for controlling suitable electrical components), and measurement equipment (e.g., to measure voltage, current, impedance, frequency, temperature, or another parameter). Processing circuitry 102 may determine charge status information e.g., charge level, whether the battery is being charged, charging current, charging voltage, charging mode, and whether a charging fault exists.

Vehicle controller 120 may further include or be in communication with communications circuitry 152 and input/output (I/O) circuitry 111. I/O circuitry 111 may be communicatively connected to display 113, input interface 114, and speaker 112. Display 113 may be located at a dashboard of vehicle 101 and/or a heads-up display at a windshield of vehicle 101. Display 113 may comprise an LCD display, an OLED display, an LED display, or any other type of display. Speaker 112 may be located at any location within the cabin of vehicle 101, e.g., at the dashboard of vehicle 101, on an interior portion of the vehicle door. In some embodiments, haptic notification may be provided. In some embodiments, the notification may be provided to user device 154 (e.g., a mobile device, such as, for example, a smartphone or a tablet or a key fob, such as via wireless or wired communication), in addition to or alternative to display 113 and speaker 112 within vehicle 101.

In some embodiments, controller 120 may be in communication (e.g., via communications circuitry 152) with user device 154 (e.g., a mobile device, a computer, a key fob, etc.). Such connection may be wired or wireless. In some embodiments, communications circuitry 152 and/or user device 154 may be in communication with a server 156 (e.g., over a communications network 155, such as, for example, the Internet, and/or a cellular telephone network and/or a satellite network and/or any other suitable network or communication technique).

It should be appreciated that FIG. 1 only shows some of the components of vehicle 101, and it will be understood that vehicle 101 also includes other elements commonly found in vehicles (e.g., electric vehicles), e.g., a motor, brakes, wheels, wheel controls, turn signals, windows, doors, etc.

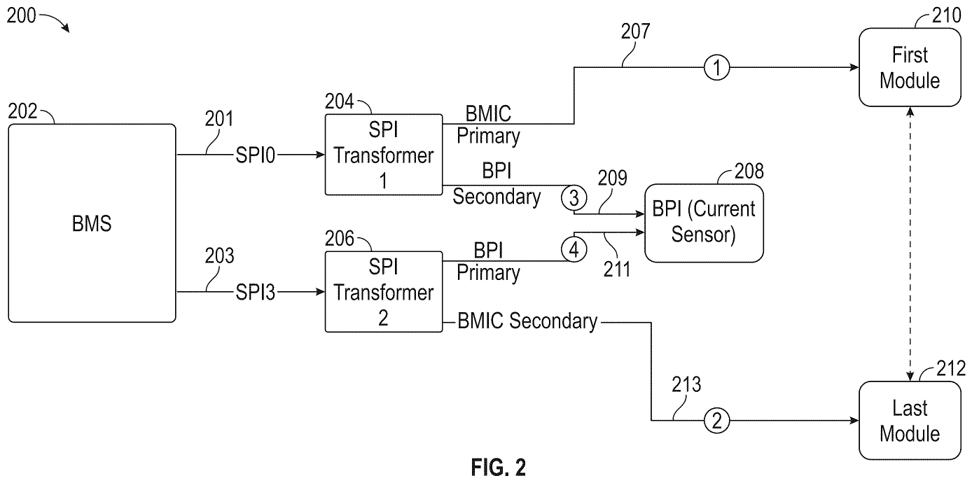

FIG. 2 shows a block diagram of a system 200 for managing the provision of sensor data to a BMS, in accordance with some embodiments of this disclosure. In some embodiments, system 200 may correspond to or be included in battery system 150 of FIG. 1. As shown in FIG. 1, BMS 202 may be coupled to battery power insulation (BPI) circuit or sensor 208, which may be configured to detect a current of a battery of vehicle 101, BMS 202 may be coupled to BPI 208 via serial peripheral interface (SPI) connection or communication line 201 and SPI connection or communication line 203, or via any other suitable type or protocol of connector or communication line. BMS 202 may comprise one or more microcontrollers, or any other suitable components, for managing a battery of vehicle 101.

In some embodiments, SPI transformer 204 may split connection 201 into a sub-connection 207 (e.g., a primary battery monitoring integrated circuit (BMIC) communication line) and a sub-connection 209 (e.g., a secondary BPI communication line). Sub-connection 207 may be coupled to module 210 of a plurality of modules of a BMIC, also referred to as a battery voltage temperature (BVT) sensor or device (e.g., an ASIC), configured to measure a temperature and voltage of modules of a battery of a vehicle 101 of FIG. 1. Sub-connection 209 may be coupled to BPI 208. SPI transformers 204 and 206 may convert SPI into isolated SPI.

In some embodiments, SPI transformer 206 may split connection 203 into a sub-connection 211 (e.g., a primary BPI communication line) and a sub-connection 213 (e.g., a BMIC secondary communication line) coupled to module 212 of a plurality of modules of the BMIC. In some embodiments, each of the plurality of modules may comprise a BMIC (each sensing voltage and temperature for that particular module), or BMIC s may be shared across multiple modules.

In some embodiments, the BMIC or BVTs may be implemented using a chain of LTC6810 devices, connected to the BMS through a loop, where such devices can communicate bidirectionally. In some embodiments, the BPI 208 may measure battery power and current, e.g., using one or more LTC2949 devices. The BPI 208 may be accessed through either isoSPI port.

In some embodiments, connections 209 and 211 may be traces of a printed circuit board (PCB) on which BPI may be included. Connection 207 and 213 may, on the other hand, be located at a distance from BMS 202, and thus may be harnesses or other connectors or wires which are not traces on a PCB.

In some embodiments, in system 200, in order for isolated SPI (isoSPI) traffic to execute properly, either the combination of connections 207 and 211 (e.g., BMIC primary and BPI primary) are utilized to transmit sensor data (without utilizing connection 209 and 213), or the combination of connections 209 and 213 (e.g., BMIC secondary and BPI secondary) are utilized to transmit sensor data (without utilizing connection 207 and 211). In some embodiments, in order to send traffic to both sides of the chain, a transaction takes place in two ticks across the 5 ms isoSPI task cadence. In some embodiments, in order to handle switching from primary to secondary on a per-transaction basis, system 200 reads a Boolean dictating whether bi-directional isoSPI (BDI) mode is set. Upon determining that such mode is set, the chosen device may alternate from primary to secondary and vice-versa on every subsequent isoSPI step invocation.

The current architecture shown in FIG. 2 uses two SPI lines shared between BPI 208 and BMIC (e.g., modules 210, 210, . . . ) to sense cell voltage and pack current/voltage data. In some embodiments, by default, connector 201 (SPI 0) is connected to connector 207 (BMIC primary) which senses cell voltage data from first module 210 to last module 212, and connector 203 (SPI 3) is connected to connector 211 (BPI primary) which senses pack current and voltage data from a shunt and voltage sensors on the pack. In some embodiments, BPI 208 may be connected to the shunt to sense battery pack current, battery pack voltage, isolation resistance across the battery pack, e.g., to detect/sense short circuits in the battery pack.

In some embodiments, system 200 may provide for bi-directional isoSPI communication support on a broken chain. For example, system 200 may perform certain actions if a defect or failure of sub-connection 209 or 211 (e.g., a PCB trace) is detected, e.g., to support broken chains by sending data across both sides of the chain. In some embodiments, both the BMIC and BPI devices use PEC values to ensure reliable communication between the device (e.g., the BMIC 210, 212 or BPI 208) and the host microcontroller (e.g., the BMS 202).

In some embodiments, any of the communication lines 207, 209, 211, or 213 (labeled as 1, 2, 3, 4, respectively) can break. For example, lines 1 and 2 may be physical harnesses which can break due to variety of failure modes (e.g., recessed pins, bad quality connectors, pinched wires). Lines 3 and 4 may be PCB traces, where failure may be detected in relation to potential failure mode on a choke coil on these lines which can result in no communication from the BPI sensor 208.

In some embodiments, if there is a breakage of either connection 207 or connection 211, BMS 202 may cause the SPIs to be swapped in an alternate fashion to be able to communicate with both the sensors (208 and 210, 212, . . . ), to enable obtaining data for the BMS to keep vehicle 101 functional, where otherwise vehicle 101 may be configured to open contactors due to unavailability of the sensed data which would result in loss of propulsion. For example, if there is breakage on line 1 (connection 207 of FIG. 2) and line 3 (connection 209) the vehicle may be shut off, by grounding the vehicle and opening contactors. In some embodiments, a similar technique may be used in relation to failures of BMIC primary connection 207 or BMIC secondary connection 213. For example, a breakage may occur between any two BMICs in a daisy chain of, e.g., 9 BMICs. In some embodiments, the BMICs may be laid out as, e.g., nine separate single-device daisy chains instead of a single, contiguous daisy chain (e.g., the independent connections would build inherent redundancy).

BMS 202 may switch the BMIC SPI from BMIC primary (connector 207) to BMIC secondary (connector 213), which provides the ability to sense data from last module 212 to first module 210, to enable data from each of the modules to be fetched. For example, the SPI of BPI primary (connection 211) is also switched to BPI secondary (connection 209), as BMS 202 is not able to communicate with two different sensors on the same SPI line at the same time, to enable the pack current and voltage data to be sensed correctly.

In some embodiments, a breakage may be detected using PEC errors, e.g., if PEC errors persist for a predetermined duration of time, then loss of BPI 208 communications may be confirmed. Once the fault is matured, SPI buffers may be swapped between BMIC and BPI, to ensure regaining communications to BPI 208 (over the other SPI comms line which is assumed to be intact) and healing the PEC errors. The vehicle can keep functioning if all the data sensed from BMIC and BPI is confirmed to be valid. In some embodiments, BMS 202 may provide for output an indication (e.g., provide a displayed element or light up an indicator on a vehicle dashboard) to notify the driver about this breakage, while still retaining the ability to drive the vehicle.

In some embodiments, in detecting a broken chain, because C-pin measurements may be the most frequent set of commands set across each subsequence of the BMIC sequence, the system may rely on the PEC errors found in the first register group of that respective isoSPI transaction. Specifically, the system may check for 3 or more consecutive PEC errors on a specific ASIC from multiple transactions. PEC error healing may be employed as part of the switching, e.g., the switch may be implemented quicker than the debounce time (e.g., 1.5 seconds) for PEC errors. In some embodiments, once traffic resumes on both sides of the breakage, future commands may not feature the PEC errors found during initial detection.

In some embodiments, system 200 may check the BMIC communication state, e.g., every 5.0 ms, and may check the BPI communication state, e.g., every 5.0 ms, or every 2.0 ms.

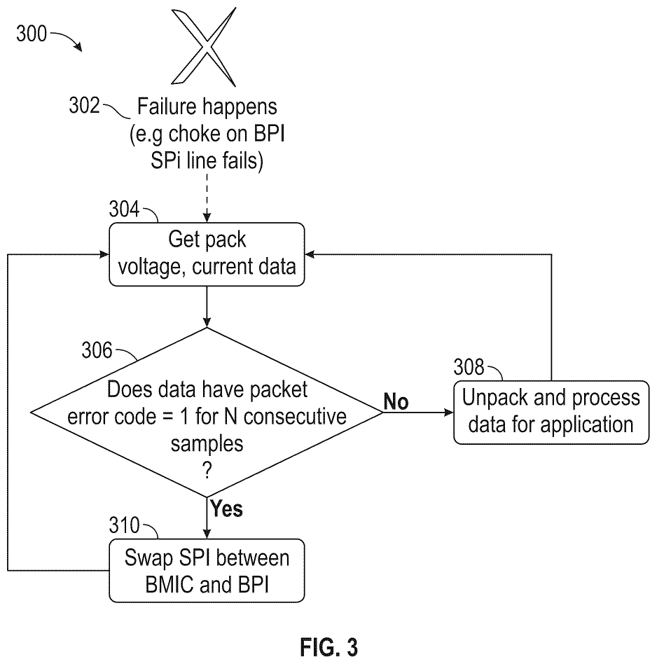

FIG. 3 shows an illustrative flowchart for managing the provision of sensor data to a BMS, in accordance with some embodiments of this disclosure. At 302, BMS 202 may detect that failure has occurred (e.g., a choke on BPI SPI line 209 or 211 fails, such as a ceramic portion thereof cracks, causing an interruption for traces in a PCB and which may disconnect a SPI, and/or a thermal event occurs causing such breakage). At 304, BMS 202 may obtain pack data, including voltage data, e.g., measured by BMIC 210, 212, and current data, e.g., measured by BPI 208. At 306, the BMS may determine whether data has a PEC=1 for N consecutive samples (e.g., 3 consecutive samples); if so, processing proceeds to 308, and subsequently to 304 to continue evaluating sensor data. Otherwise, processing proceeds to 310. At 310, having identified a breakage using PEC errors persisting or a predetermined duration, BMS 202 confirms the loss of BPI communications, and may switch the SPI connections in real time to keep receiving data from each the sensors 209 and 210, . . . 212. In the switching phase, once the fault is matured, SPI buffers are swapped between BMIC and BPI to regain communications over an intact SPI line, thereby healing the PEC errors. This ensures the vehicle can continue functioning if all data from BMIC and BPI is validated. In some embodiments, BMS 202 may provide for output an indication (e.g., provide a displayed element or light up an indicator on a vehicle dashboard) to notify the driver about this breakage, while still retaining the ability to drive the vehicle.

System 200 may enable communication with all BMIC devices after the SPI chain breaks in one spot. The BMIC chain and BPI device may share the same two QSPI ports, and use PECs to validate incoming commands, and both BMIC 210, 212 and BPI 208 devices may transmit PECs for verification by the host. In some embodiments, if a PEC fails, the associated data may not be usable.

System 200 may provide a battery pack architecture in which two connectors (e.g., SPIs 201 and 203) are shared across two sensors (e.g., the BMIC(s) and BPI) such that the connectors can be alternated. In some embodiments, in a default configuration, connector 201 is used to communicate with BMIC modules 210, 212 . . . , and connector 203 is used to receive sensor data from BPI 208.

In some embodiments, upon detecting a breakage (e.g., based on PEC code(s)) between any of modules 210, 212, . . . , BMS 202 may use connection 201 to obtain data from module(s) which remain intact (e.g., above the broken module in FIG. 2), and may use connection 203 to obtain data from module(s) which remain intact (e.g., below the broken module in FIG. 2), and stitch such data together, e.g., to obtain a portion of the data from connectors 201 and 207, and the other portion of the data from connectors 203 and 213. This may enable vehicle 101 to continue to be driven, as data from each of the modules may be obtained.

In some embodiments, one of connector 201 or 203 is used to obtain BMIC sensor data, and the other of connector 201 or 203 is used to obtain BPI sensor data, e.g., different sensor data may be communicated in parallel using connectors 201 and 203, e.g., while no breakage is occurring in the PCB traces of 209, 211 or the wires 207, 213. In some embodiments, system 200 may alternate between (i) providing BPI sensor data 208 by way of connectors 203 and 211 to BMS 202 and providing BMIC sensor data by way of connectors 201 and 207 and (ii) providing BPI sensor data 208 by way of connectors 201 and 209 to BMS 202 and providing BMIC sensor data by way of connectors 203 and 213.

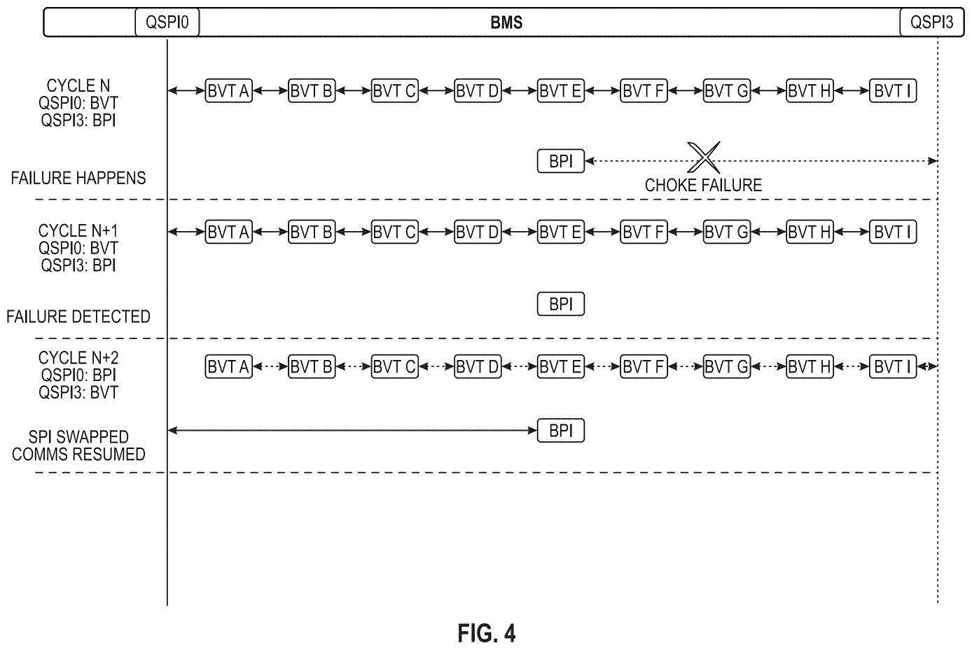

FIG. 4 shows an illustrative diagram for managing the provision of sensor data to a BMS, in accordance with some embodiments of this disclosure. As shown in FIG. 4, at N+1 a failure is detected at quad serial peripheral interface (QSPI) 3 based on a choke failure occurring at cycle N when BVT sensor data is being provided via QSPI0 and BPI sensor data is being provided at BPI3. At cycle N+1, the connections are swapped, e.g., BPI sensor data begins being provided via QSPI0 instead of QSPI3, and BVT sensor data begins being provided via QSPI0.

In some embodiments, in system 200, communication may be interleaved across two QSPI ports, and at least two different configurations may be implemented. In the first configuration, a BVT chain communicates through SPI0 (QSPI0) and a BPI device communicates through SPI2 (QSPI3); in the second configuration, the BVT chain communicates through SPI1 (QSPI3) and the BPI device communicates through SPI3 (QSPI0). In some embodiments, the application changes the configuration on every communication cycle.

In some embodiments, interleaved communication is automatic. In some embodiments, the application does not need to dynamically change the behavior of the BPI or BVT drivers to accommodate a failure in the communication bus.

In some embodiments, asynchronous operation of two peripheral drivers through the same QSPI port requires an interrupt event manager. Interleaving allows each driver to operate independently without worrying about losing arbitration of the QSPI port.

In some embodiments, with one BVT chain failure, data is still delivered to consumer software components. These software components can still operate without caring about the manner by which the data was received. In some embodiments, failures are detectable by comparing received versus expected PEC values, and can therefore be reported to a fault manager.

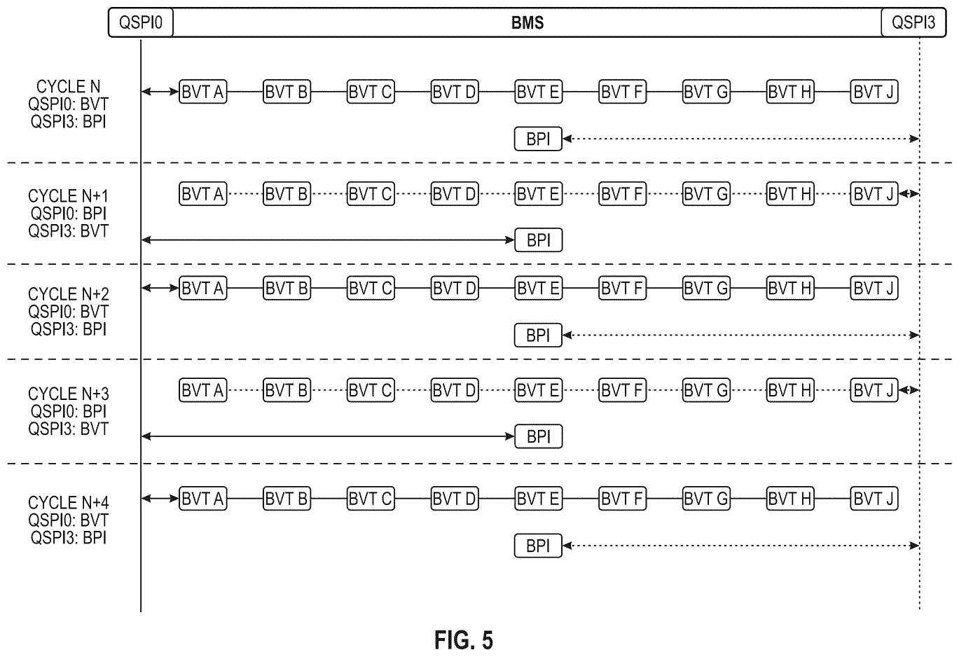

FIG. 5 shows an illustrative diagram for managing the provision of sensor data to a BMS, in accordance with some embodiments of this disclosure. In some embodiments, as shown in FIG. 5, in normal operation, both QSPI ports are utilized in a ping-pong pattern. In some embodiments, this is the manner in which communication will occur for (ideally) the entire life of the BMS.

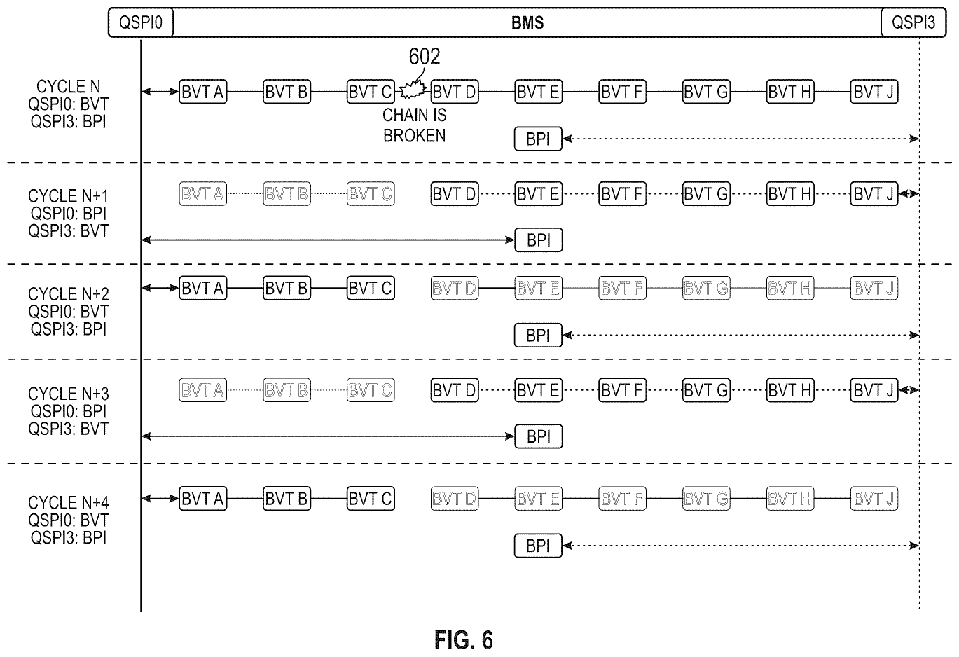

FIG. 6 shows an illustrative diagram for managing the provision of sensor data to a BMS, in accordance with some embodiments of this disclosure. FIG. 6 illustrates a failure of a single BVT chain break, where the device chain is physically broken in one spot 602. The failure is detectable by checking PEC values that are included in received read-back data. In some embodiments, missing PEC values report back as zero. In some embodiments, all devices are still accessible through one QSPI port, all data is still available to application consumer component, and BVT data throughput is cut in half (the system is running in a degraded state).

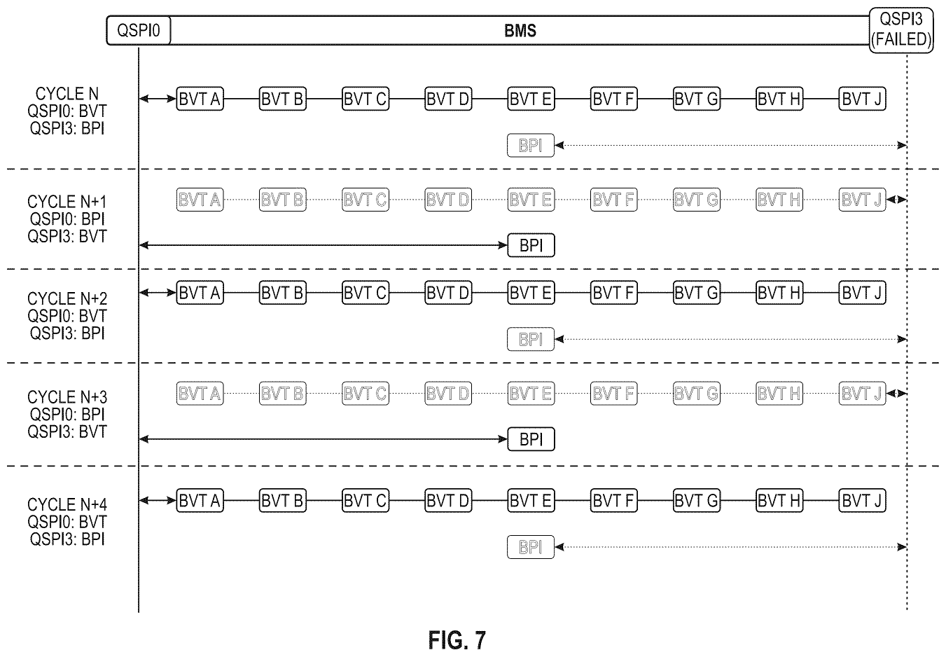

FIG. 7 shows an illustrative diagram for managing the provision of sensor data to a BMS, in accordance with some embodiments of this disclosure. FIG. 7 illustrates a QSPI port failure, where, for example, a stuck interrupt or a corrupted pin configuration may have caused a QSPI port (e.g., QSPI3) to have failed. The failure is detectable by checking QSPI timeout/error flags. In some embodiments, all devices are still accessible through one QSPI port, all data is still available to application consumer components, BVT and BPI data throughput is cut in half, and the system is running in a degraded state.

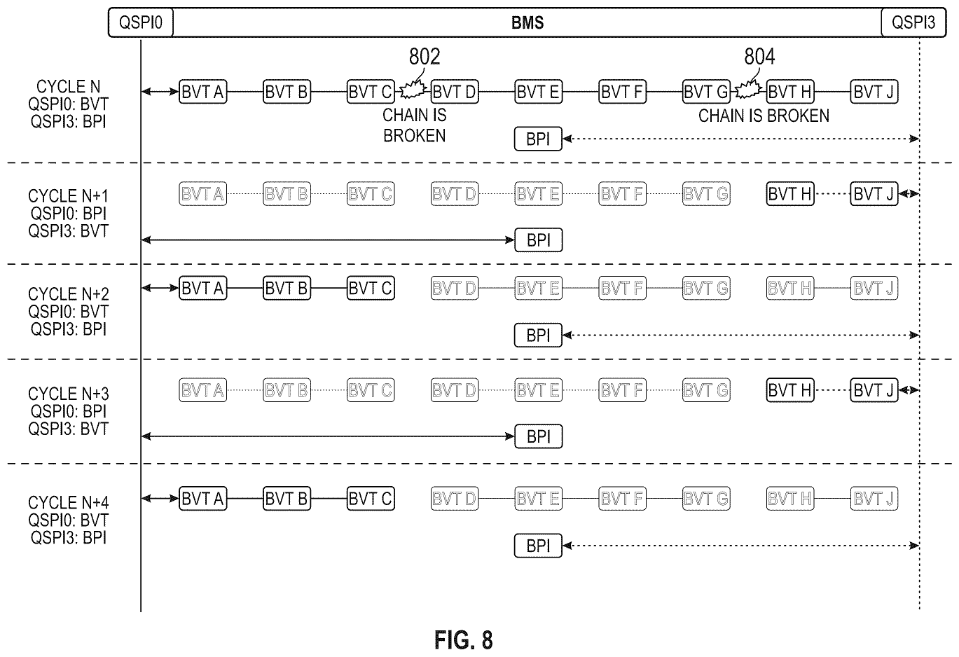

FIG. 8 shows an illustrative diagram for managing the provision of sensor data to a BMS, in accordance with some embodiments of this disclosure. FIG. 8 illustrates multiple BVT chain breaks at 802 and 804. In this state, there is not enough redundancy to continue operating the BMS, and such is detectable by checking PEC values that are included in received read-back data, where missing PEC values reports back as zero.

In some embodiments, in a non-limiting example, battery voltage and/or temperature values (measured by the BVTs) are read at 10.0 Hz (every 100.0 milli-seconds), and battery power/current values (measured by the BPI) are read at 200.0 Hz (every 5.0 milli-seconds). Communication timing may be configured such that it accommodates interleaved communication and does not interfere with sample rates through the BVT or BPI. In some embodiments, for every one communication cycle of the BVT, there may be ten communication cycles for the BPI.

Asynchronous SPI communication significantly reduces CPU load, allowing faster sampling rates. Such asynchronous communication may be implemented in the aforementioned ping-pong solution. In some embodiments, the communication cycle pattern of such the ping-pong communication configuration may be as follows: BVT communication cycle begins on QSPI0, which may take somewhere between 0.0 and 50.0 or 100.0 milli-seconds to complete; BPI communication cycle is much shorter (<5.0 ms), and runs through QSPI3, independent from whatever is happening on QSPI0; BVT communication cycle begins on QSPI3, and BPI is switched to QSPI0 and continues as normal without interruption; BVT communication cycle begins on QSPI0, and BPI is switched to QSPI3.

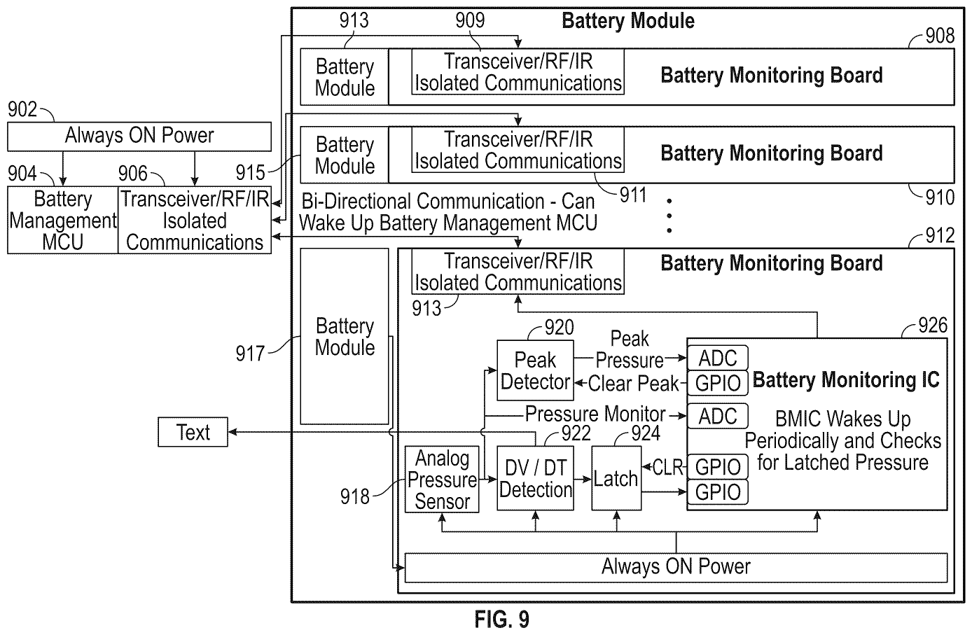

FIG. 9 shows an illustrative system for implementing a bi-directional mode for current and voltage sensing and a hardware circuit to detect pressure spikes when a battery pack of a vehicle (e.g., vehicle 101 of FIG. 1) is undergoing a thermal event, and waking up a BMS via an interrupt, in accordance with some embodiments of this disclosure. In some embodiments, system 900 comprises BMS 902 which may comprise battery management microcontroller unit (MCU) 904 and may communicate via transceiver 906 (for RF/IR isolated communications) with transceivers 909 and 911 of battery managing boards 908 and 910. Battery monitoring board 912 may communicate with BMS 902 by way of transceiver 913. In some embodiments, battery managing board 908, 910 associated with a plurality of battery modules 915, 919 may be implemented in a similar manner as battery module managing board 912 associated with battery module 917.

Battery monitoring board 912 may comprise hardware circuitry to monitor pressure buildup in the battery pack. In some embodiments, when pressure exceeds a predetermined threshold (e.g., if the battery undergoes a thermal event, there may be a spike in pressure buildup in the battery pack), the hardware circuitry generates a rising edge to wake up BMS 902. BMS 902 then enables real-time pressure monitoring over a communication line (e.g., SPI), allowing thermal event detection software to confirm a thermal event. Upon confirmation, appropriate actions such as, for example, waking up the rest of the vehicle, deploying pyrotechnic fuses (leading to either preventing or delaying propagation), and/or sending notifications for emergency calls (e.g., XMM for e-call) may be taken. This hardware-based detection may be faster and more efficient than software detection, as it allows BMS 904 to remain asleep, saving battery power and enabling quicker response times.

Each battery module 913, 915, 917 may be associated with an analog pressure sensor 918 in communication with peak detector circuitry 920, which may measure whether sensor data received from pressure sensor 918 exceeds a threshold, and may latch such data if the threshold is exceeded. DV/DT detection circuitry 922 may measure how quickly (slope of) the pressure in battery pack measured by sensor 918 is rising. In some embodiments, circuitry 922 may latch at circuitry 924, e.g., a flip-flop circuit, data based on detecting a rate of change of the pressure rise exceeds a threshold. The peak pressure may be communicated by peak detector circuitry 920 to an ADC of battery monitoring IC 926 (e.g., a BVT), and latch 924 may transmit latched data to a GPIO of BVT 926. BVT 926 may be configured to periodically wake up and check for latched pressure values. Sensor 918 may transmit a pressure reading to an ADC of BVT 926. A high-voltage battery (HV) may provide always on power to the components of battery monitoring board 912.

When pressure spikes, if the vehicle is asleep, pressure spikes may not be detected by BMS 902, whereas if the vehicle is awake such pressure spikes may be detected by BMS 902 in real time. When the vehicle is sleeping, the components 918, 920, 922, and 924 may be always powered, and such circuitry may latch data if the pressure reaches a threshold or if a slope of pressure rise exceeds a threshold, and such circuitry may wake up the BVT 926 with the latched pressure data. Once BVT 926 wakes up, the BVT in turn may wake up BMS 902, and once woken up from a sleep mode, BMS 902 may read the latched values and confirm if the values are indicative of a false trigger, or a confirmed thermal event in relation to the battery pack. For example, BMS 902 may perform gas concentration (e.g., checking for increasing hydrogen, carbon monoxide, carbon dioxide levels indicative of a thermal event) measurements, and/or other measurements (e.g., checking for increasing temperature, voltage levels indicative of a thermal event) to determine whether the event is a false trigger or a thermal event. BMS 902 may be configured to make real-time measurements, or at a higher sampling rate as opposed to measurements taken by the components of battery monitoring board 912 when BMS 902 is in the sleep mode. This may be advantageous in that BMS 902 does not need to remain awake at all time to monitor pressure spikes. In some embodiments, BMS 902 may be woken up according to a duty cycle (e.g., every 2 seconds) to perform measurements. In some embodiments, the BVT ASIC may be implemented on a PCB on which one or more of components 918, 920, 922, and 924 may also be provided.

If the BVT wakes up the BMS (e.g., via an interrupt signal), the BMS may take direct action without monitoring signals itself, or the BMS may stay awake and perform its own monitoring of signals to confirm whether an action is to be taken. The BVT may transmit an indication to the BMS regarding the pressure values, and/or to monitor the pressure values more quickly, which the BMS may otherwise be asleep and miss a relatively short window (e.g., 1-2 seconds) to measure the initial pressure spike.

Analog pressure sensor 918 may sense a pressure build up, and input this sensed pressure to peak detector circuitry 920, which in turn detects pressure peak above a predetermined threshold, e.g., which can be set based on pack tests and which can be different for different cell chemistries. This peak pressure is detected by an ADC on the BMIC or BVT 926. The BMIC has a way to clear this peak pressure latch using a GPIO for a subsequent detection. A separate ADC also monitors actual pressure. Analog pressure sensor 918 inputs the sensed pressure value to a DV/DT detection logic circuit 922, which logic keeps track of the rate of change of pressure build up. If the rate goes beyond a certain value, this logic latches the slew which can be read by BMIC 926, which periodically wakes up and reads the pressure peak and the latch. If pressure peak and latch are set, BMIC wakes up the BMS via an interrupt. BMS 902 senses these signals and confirms thermal event to take appropriate reactions.

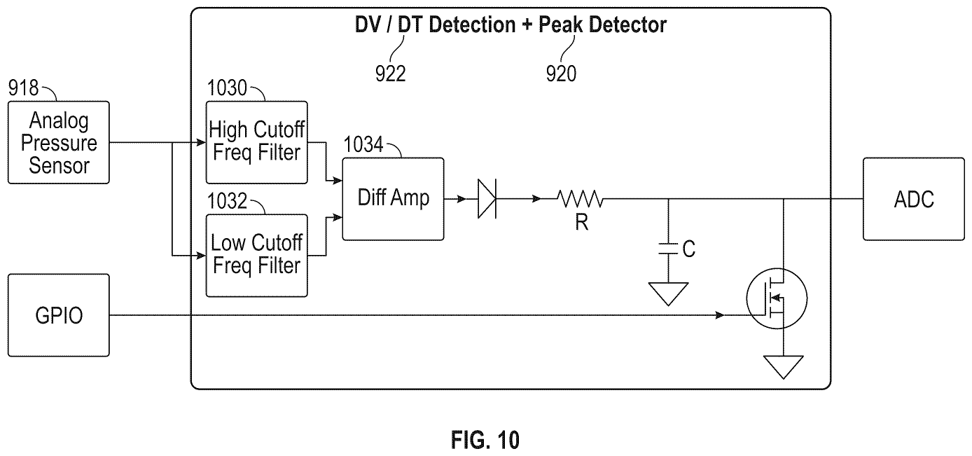

FIG. 10 shows a detailed view of the DV/DT detection circuitry 922 and peak detector circuitry 920, in accordance with some embodiments of this disclosure. Analog pressure sensor 918 may input sensor data to high cutoff frequency filter 1030 and low cutoff frequency filter 1032, and signals from such filters may be input to differential amplifier 1034. The signal may flow through other circuit components, e.g., a diode, resistor, capacitor and/or transistor, to an ADC of BVT 926.

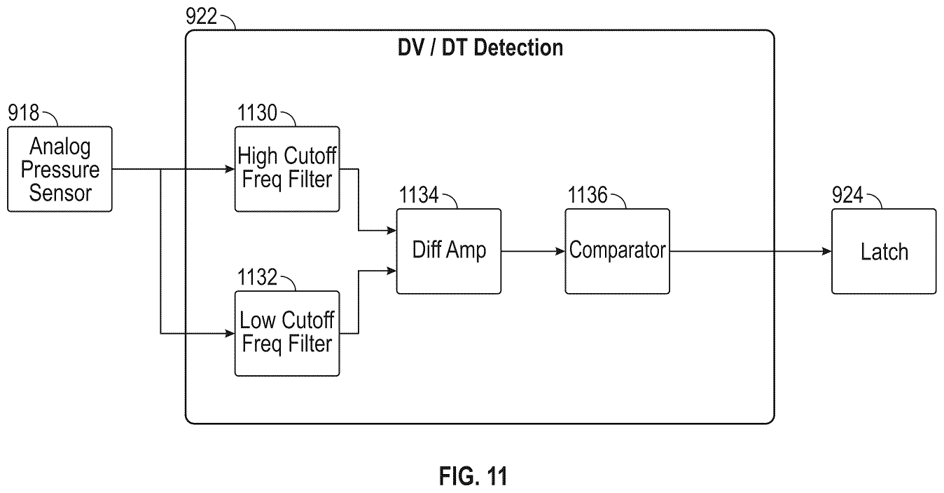

FIG. 11 shows a detailed view of the DV/DT detection circuitry 922, in accordance with some embodiments of this disclosure. Analog pressure sensor 918 may input sensor data to high cutoff frequency filter 1130 and low cutoff frequency filter 1132, and signals from such filters may be input to differential amplifier 1134. A signal from differential amplifier 1134 may be input to comparator 1136 (e.g., to determine whether the rate of change of the pressure rise exceeds a threshold) and if so, latched at latch 924.

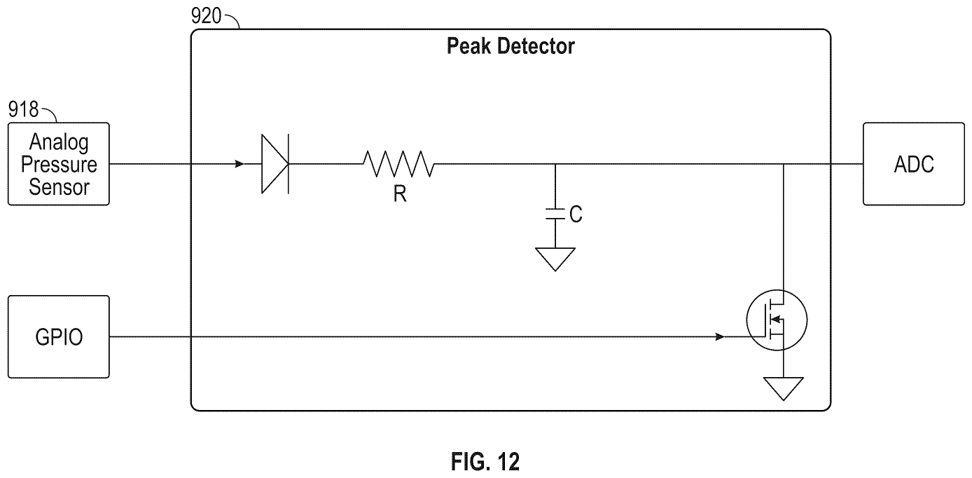

FIG. 12 shows a detailed view of the peak detector circuitry 920, in accordance with some embodiments of this disclosure. Analog pressure sensor 918 may input sensor data to other circuit components, e.g., a diode, resistor, capacitor and/or transistor, to an ADC of BVT 926. The peak detector circuitry 920 may determine whether the pressure indicated by the sensor data received from analog pressure sensor 918 exceeds a threshold and, if so, may communicate such result an ADC of BVT 926.

In some embodiments, the vehicles, devices and systems disclosed herein may be employed to perform duty cycling (e.g., of cores of a controller or microcontroller) to support sleep power estimation. A DC-DC source (e.g., a mini DC-DC) may support all 12 V battery loads when the vehicle (e.g., the BMS) is sleeping. This results in vehicle loads consuming power from high-voltage (HV) battery, thus depleting the battery. The vehicles, devices, and systems disclosed herein may perform duty cycling while the vehicle is sleeping, to provide the BMS an opportunity to measure the power draw from the HV pack, while minimizing the impact on the 12 V battery life.

The BMS may be cycled on to measure power draw, as there may be an expectation that the load is drawing a certain amount of power when the vehicle is sleeping. Once the BMS is sleeping, measurements taken by the BMS prior to entering the sleep mode may be relied upon, as the BMS may not have the visibility to the load profile while in the sleep mode. Thus, any change in load profile (e.g., due to a security system operating in a parking lot recording video in a vicinity of the vehicle and/or data uploading to a cloud server) may not be captured, which may lead to overestimation or underestimation of state-of-charge (SOC) of the battery. The BMS may be woken up periodically to do actual measurements of a current being drawn by a load of the battery, which may be used to estimate the SOC.

In some embodiments, while the BMS is sleeping, estimates may be calculated for a load/power draw or a current SOC, e.g., for storage in memory to be accessed by the BMS when the BMS wakes up. The estimator may be based on, for example, measured voltage and current before the vehicle goes to sleep, and a historical profile for the vehicle in similar historical scenarios. The BMS may be cycled on to perform a real-time determination for a load/power draw or of the SOC, to correct such estimate based on the determination.

In some embodiments, the estimated current draw may be compared to the actual measurement, to determine if the estimation is accurate. If the estimation is accurate (e.g., within a certain threshold), the vehicle may decrease how often the BMS is cycled on to perform the real-time measurement of the current draw of the battery (and determination of the SOC). On the other hand, if the estimation is inaccurate (e.g., outside a certain threshold), the vehicle may increase how often the BMS is cycled on to perform the real-time measurement of current draw and determination of the SOC of the battery, based on measured current draw when the BMS awakes. In some embodiments, the measured value of the current draw (or determined SOC) obtained when the BMS is cycled on may replace the estimated value in memory, e.g., if the estimated value is incorrect, or is off by a certain threshold, for a single measurement or for a threshold number of measurements over a threshold period of time (e.g., while the vehicle is parked in a parking lot or garage). Estimates may be validated periodically, and if the estimate deviates (e.g., a threshold number of times in a location) by more than a threshold amount from the measurements of the current draw or determination of the SOC when the BMS is woken up according to the duty cycle, the duty cycle may be updated to cause the BMS to be cycled back on to take measurements more frequently.

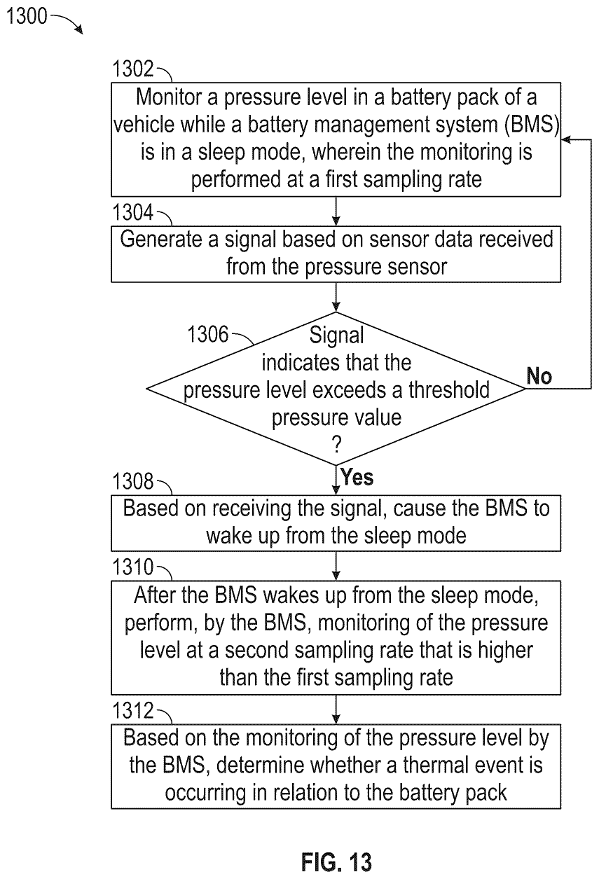

FIG. 13 shows an illustrative flowchart 1300 for determining whether a thermal event is occurring in relation to a battery pack based on a monitored pressure level, in accordance with some embodiments of this disclosure. At 1302, pressure sensor 918 may be used to monitor a pressure level in a battery pack of a vehicle while BMS 902 is in a sleep mode. Such monitoring may be performed at a first sampling rate. At 1304, battery monitoring circuitry, such as, for example, peak detector circuitry 920 (and/or other circuitry of battery monitoring board 912, such as 918, 920, 922, and/or 924), may receive the sensor data and generate a signal based on sensor data received from the pressure sensor 918. For example, at 1306, if such signal indicating that the pressure level exceeds a threshold pressure value, processing may proceed to 1308. Otherwise, processing may revert to 1302.

At 1308, based on receiving such signal indicating that the pressure level exceeds a threshold pressure value, the battery monitoring circuitry may cause BMS 902 to wake up from the sleep mode (e.g., using an interrupt signal). In some embodiments, based on receiving data indicating a rate of change of the pressure level exceeds a threshold value, a second signal may be generated (and latched), where BMS 902 may be caused to wake up based on such second signal. At 1310, after BMS 902 wakes up from the sleep mode, BMS 902 may perform monitoring of the pressure level at a second sampling rate that is higher than the first sampling rate indicated at 1302. In some embodiments, the second sampling rate may correspond to real-time monitoring of the pressure level. At 1312, based on the monitoring of the pressure level by the BMS 902, BMS 902 and/or other circuitry may determine whether a thermal event is occurring in relation to the battery pack. If so, an ameliorative action may be initiated, e.g., waking up each of a plurality of other components of the vehicle, deploying one or more pyrotechnic fuses, transmitting a notification to a driver (or other occupant) of the vehicle, and/or transmitting a notification to an emergency service.

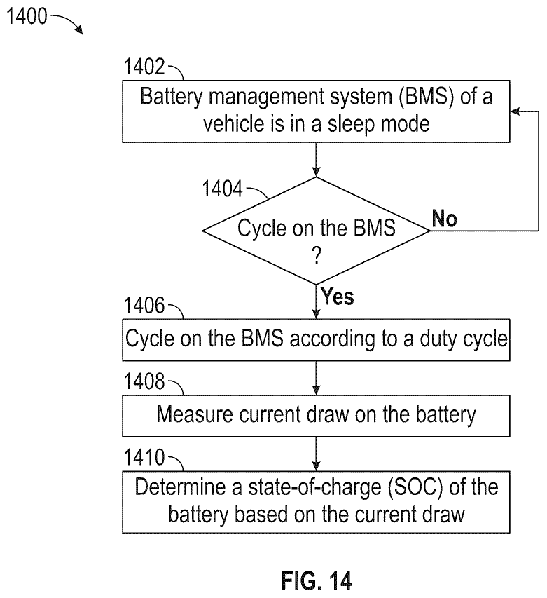

FIG. 14 shows an illustrative flowchart 1400 for cycling on a BMS and measuring a current draw on a battery, in accordance with some embodiments of this disclosure. At 1402, BMS 902 of a vehicle may be in a sleep mode. At 1404, circuitry of vehicle may determine whether to cycle on BMS 902. If so, processing may proceed to 1406; otherwise processing may revert to 1404, where BMS 902 remains asleep. At 1406, BMS 902 may be cycled on according to a duty cycle. For example, BMS 902 may be woken up periodically to perform a measurement of a current being drawn by a load of the battery (at 1408), and such current draw may be used to determine or estimate the SOC (at 1410). In some embodiments, BMS 902 is configured to determine the SOC when the vehicle is turned on. In some embodiments, BMS 902 causes the measured current draw to replace a value for the current draw stored in a memory of the vehicle, e.g., based on determining that the value for the current draw stored in the memory deviates from the measured current draw by a threshold amount.

In some embodiments, circuitry of the vehicle is configured to, while the BMS is in the sleep mode, estimate the SOC of the battery. The BMS may, based on determining that such estimate is within a threshold value of the SOC of the battery measured by the BMS, decrease a frequency that the BMS is cycled on by updating the duty cycle. For example, such updating may be performed based on determining that each of a plurality of estimated SOCs of the battery calculated while the BMS is in the sleep mode is within the threshold value.

In some embodiments, circuitry of the vehicle is configured to, while the BMS is in the sleep mode, estimate the SOC of the battery. Based on determining that the estimate is not within a threshold value of the SOC of the battery measured by the BMS, the BMS may increase a frequency that the BMS is cycled on by updating the duty cycle. Such updating may be performed based on that each of a plurality of estimated SOCs of the battery calculated while the BMS is in the sleep mode is not within the threshold value.

The foregoing is merely illustrative of the principles of this disclosure, and various modifications may be made by those skilled in the art without departing from the scope of this disclosure. The above-described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations to and modifications thereof.

We claim:

1. A vehicle comprising:
a battery;
circuitry configured to, while a battery management system (BMS) is in a sleep mode:
cycle on the BMS according to a duty cycle;
wherein the BMS is configured to, after being cycled on:
measure current draw on the battery; and
determine a state-of-charge (SOC) of the battery based on the current draw.

2. The vehicle of claim 1, wherein the BMS is configured to determine the SOC when the vehicle is turned on.

3. The vehicle of claim 1, further comprising:
memory,
wherein the BMS causes the measured current draw to replace a value for the current draw stored in the memory.

4. The vehicle of claim 3, wherein the BMS causes the measured current draw to replace the value for the current draw stored in the memory based on determining that the value for the current draw stored in the memory deviates from the measured current draw by a threshold amount.

5. The vehicle of claim 1, wherein:
the circuitry is further configured to, while the BMS is in the sleep mode, estimate the SOC of the battery; and
the BMS is further configured to:
based on determining that the estimate is within a threshold value of the SOC of the battery measured by the BMS, decrease a frequency that the BMS is cycled on by updating the duty cycle.

6. The vehicle of claim 5, wherein the BMS is further configured to decrease the frequency that the BMS is cycled on by updating the duty cycle based on determining that each of a plurality of estimated SOCs of the battery calculated while the BMS is in the sleep mode is within the threshold value.

7. The vehicle of claim 1, wherein:
the circuitry is further configured to, while the BMS is in the sleep mode, estimate the SOC of the battery; and
the BMS is further configured to:
based on determining that the estimate is not within a threshold value of the SOC of the battery measured by the BMS, increase a frequency that the BMS is cycled on by updating the duty cycle.

8. The vehicle of claim 7, wherein the BMS is further configured to increase the frequency that the BMS is cycled on by updating the duty cycle based on determining that each of a plurality of estimated SOCs of the battery calculated while the BMS is in the sleep mode is not within the threshold value.

9. A method comprising:
while a battery management system (BMS) of a vehicle is in a sleep mode, using circuitry to cycle on the BMS according to a duty cycle;
after the BMS is cycled on, using the BMS to:
measure current draw on a battery; and
determine a state-of-charge (SOC) of the battery based on the current draw.

10. The method of claim 9, wherein the BMS determines the SOC when the vehicle is turned on.

11. The method of claim 9, wherein the BMS causes the measured current draw to replace a value for the current draw stored in a memory.

12. The method of claim 11, wherein the BMS causes the measured current draw to replace the value for the current draw stored in the memory based on determining that the value for the current draw stored in the memory deviates from the measured current draw by a threshold amount.

13. The method of claim 9, further comprising:
while the BMS is in the sleep mode, using the circuitry to estimate the SOC of the battery; and
using the BMS to, based on determining that the estimate is within a threshold value of the SOC of the battery measured by the BMS, decrease a frequency that the BMS is cycled on by updating the duty cycle.

14. The method of claim 13, wherein decreasing the frequency that the BMS is cycled on by updating the duty cycle comprises determining that each of a plurality of estimated SOCs of the battery calculated while the BMS is in the sleep mode is within the threshold value.

15. The method of claim 9, wherein:
while the BMS is in the sleep mode, using the circuitry to estimate the SOC of the battery; and
using the BMS to, based on determining that the estimate is not within a threshold value of the SOC of the battery measured by the BMS, increase a frequency that the BMS is cycled on by updating the duty cycle.

16. The method of claim 15, wherein increasing the frequency that the BMS is cycled on by updating the duty cycle is based on determining that each of a plurality of estimated SOCs of the battery calculated while the BMS is in the sleep mode is not within the threshold value.

17. A non-transitory computer-readable medium having first non-transitory computer-readable instructions encoded thereon and second non-transitory computer-readable instructions encoded thereon, wherein:
execution of the first non-transitory computer-readable instructions by circuitry causes the circuitry to, while a battery management system (BMS) of a vehicle is in a sleep mode:
cycle on the BMS according to a duty cycle; and
execution of the second non-transitory computer-readable instructions by the BMS causes the BMS, after being cycled on, to:
measure current draw on a battery; and
determine a state-of-charge (SOC) of the battery based on the current draw.

18. The non-transitory computer-readable medium of claim 17, wherein the BMS determines the SOC when the vehicle is turned on.

19. The non-transitory computer-readable medium of claim 17, wherein execution of the second non-transitory computer-readable instructions causes the BMS to cause the measured current draw to replace a value for the current draw stored in a memory.

20. The non-transitory computer-readable medium of claim 19, wherein execution of the second non-transitory computer-readable instructions causes the BMS to cause the measured current draw to replace the value for the current draw stored in the memory based on determining that the value for the current draw stored in the memory deviates from the measured current draw by a threshold amount.
